(19) United States
(12) Patent Application Publication
(10) Pub. No.: US 2021/0017669 A1
(43) Pub. Date: Jan. 21, 2021

(54) SEMICONDUCTOR EPITAXIAL STRUCTURE AND METHOD OF FORMING THE SAME

(71) Applicant: GlobalWafers Co., Ltd., Hsinchu (TW)

(72) Inventors: Yen-Lun Huang, Hsinchu (TW); Ke-Hong Su, Hsinchu (TW); Ying-Ru Shih, Hsinchu (TW)

(73) Assignee: GlobalWafers Co., Ltd., Hsinchu (TW)

(21) Appl. No.: 16/920,318

(22) Filed: Jul. 2, 2020

(30) Foreign Application Priority Data
Jul. 19, 2019 (TW) 108125591

(51) Int. Cl. C30B 25/18; H01L 21/02; H01L 29/20; H01L 29/205; H01L 29/778; C30B 25/10; C30B 29/40

(52) U.S. Cl. CPC C30B 25/183; C30B 29/403; H01L 21/02381; H01L 21/02378; H01L 21/02389; H01L 21/02395; H01L 21/02392; H01L 21/02458; H01L 21/02507; H01L 21/0251; H01L 21/0254; H01L 21/0262; H01L 21/02631; H01L 29/2003; H01L 29/205; H01L 29/7786; C30B 25/105; C30B 29/406; H01L 21/0242

(57) ABSTRACT

Provided is a semiconductor epitaxial structure including a nucleation layer disposed on a substrate; a buffer layer disposed on the nucleation layer; a semiconductor layer disposed on the buffer layer; a barrier layer disposed on the semiconductor layer; and a cap layer disposed on the barrier layer. In a case where a bowing of the semiconductor epitaxial structure is less than or equal to +/−30 μm, a maximum value or a minimum value of a ratio of a thickness of the buffer layer to a thickness of the semiconductor layer is represented as following formula: Y=aX1−bX2+cX3, X1≥0 nm, X2≥750 nm, X3≥515 nm, wherein X1 is a thickness of the nucleation layer, X2 is the thickness of the buffer layer, X3 is the thickness of the semiconductor layer, a, b and c are constants respectively, and Y is a ratio of X3 to X2.

### CROSS-REFERENCE TO RELATED APPLICATION

This application claims the priority benefit of Taiwan application no. 108125591, filed on Jul. 19, 2019. The entirety of the above-mentioned patent application is hereby incorporated by reference herein and made a part of this specification.

### TECHNICAL FIELD

The invention relates to a semiconductor structure and a method of forming the same, and more particularly, to a semiconductor epitaxial structure and a method of forming the same.

### BACKGROUND

Epitaxy refers to the technology of growing new crystals on a substrate to form a semiconductor layer. Because films formed by an epitaxial process have the advantages of high purity and good thickness control, the epitaxial technology has been widely used in the manufacture of radio frequency components or power components.

In the epitaxial technology for growing a group III nitride semiconductor layer on a substrate, the difference in lattice mismatch and thermal expansion coefficient between the substrate and the group III nitride semiconductor layer can easily cause deformation on the substrate and cracks in the group III nitride semiconductor layer. In the conventional technology, a buffer layer is formed between the substrate and the group III nitride semiconductor layer to reduce the difference in lattice coefficient between the substrate and the group III nitride semiconductor layer, thereby reducing cracks.

However, a thickness mismatch between the buffer layer and the group III nitride semiconductor layer can also cause defects such as slip lines, bowing, cracks, and even fragmentation in the entire semiconductor epitaxial structure. Therefore, there is an urgent need for a semiconductor epitaxial structure and a method of forming the same that can solve or prevent the above problems.

### SUMMARY

The invention provides a semiconductor epitaxial structure and a method of forming the same which can be used to find a maximum value or a minimum value of a ratio of a thickness of the buffer layer to a thickness of the semiconductor layer in a case where a bowing of the semiconductor epitaxial structure is less than or equal to +/−30 μm.

The invention provides a semiconductor epitaxial structure, which includes a substrate, a nucleation layer, a buffer layer, a semiconductor layer, a barrier layer and a cap layer. The nucleation layer is disposed on a substrate. The buffer layer is disposed on the nucleation layer. The semiconductor layer is disposed on the buffer layer. The barrier layer is disposed on the semiconductor layer. The cap layer is disposed on the barrier layer. In a case where a bowing of the semiconductor epitaxial structure is less than or equal to +/−30 μm, a maximum value or a minimum value of a ratio of a thickness of the buffer layer to a thickness of the semiconductor layer is represented as a formula of: Y=aX1−bX2+cX3, X1≥0 nm, X2≥750 nm, X3≥515 nm, wherein X1 is a thickness of the nucleation layer, X2 is the thickness of the buffer layer, X3 is the thickness of the semiconductor layer, a, b and c are constants respectively, and Y is the ratio of the thickness of the semiconductor layer to the thickness of the buffer layer (X3/X2) and falls between the maximum value or the minimum value.

In one embodiment of the invention, the maximum value of the ratio of the thickness of the semiconductor layer to the thickness of the buffer layer is obtainable by the formula when a is 0.098167, b is 0.008583 and c is 0.005652, and the minimum value of the ratio of the thickness of the semiconductor layer to the thickness of the buffer layer is obtainable by the formula when a is 0.09546, b is −0.003735 and c is −0.012168, wherein the thickness of the nucleation layer is between 0 nm and 36 nm, the thickness of the buffer layer is between 750 nm and 1755 nm, and the thickness of the semiconductor layer is between 515 nm and 1491 nm.

In one embodiment of the invention, the maximum value is between 0.89 and 1.99, and the minimum value is between 0.29 and 0.56.

In one embodiment of the invention, the semiconductor epitaxial structure further includes a spacer layer disposed between the barrier layer and the semiconductor layer.

In one embodiment of the invention, the maximum value of the ratio of the thickness of the semiconductor layer to the thickness of the buffer layer is obtainable by the formula when a is 0.10249, b is 0.006845 and c is 0.00583, and the minimum value of the ratio of the thickness of the semiconductor layer to the thickness of the buffer layer is obtainable by the formula when a is −0.6908, b is 0.030257 and c is 0.08209, wherein the thickness of the nucleation layer is between 0 nm and 21 nm, the thickness of the buffer layer is between 750 nm and 1385 nm, and the thickness of the semiconductor layer is between 515 nm and 1141 nm.

In one embodiment of the invention, the maximum value is between 0.88 and 1.52, and the minimum value is between 0.37 and 0.57.

The invention provides a method of forming semiconductor epitaxial structure, which includes the following steps. A nucleation layer is formed on a substrate. A buffer layer is formed on the nucleation layer. A semiconductor layer is formed on the buffer layer. A barrier layer is formed on the semiconductor layer. A cap layer is formed on the barrier layer. In a case where a curvature of the semiconductor epitaxial structure is less than or equal to +/−100 km⁻¹, a maximum value or a minimum value of a ratio of a thickness of the semiconductor layer to a thickness of the buffer layer is represented as a formula of: Y=aX1−bX2+cX3, X1≥0 nm, X2≥750 nm, X3≥515 nm, wherein X1 is a thickness of the nucleation layer, X2 is the thickness of the buffer layer, X3 is the thickness of the semiconductor layer, a, b and c are constants respectively, and Y is the ratio of the thickness of the semiconductor layer to the thickness of the buffer layer (X3/X2) and falls between the maximum value or the minimum value.

In one embodiment of the invention, the maximum value of the ratio of the thickness of the semiconductor layer to the thickness of the buffer layer is obtainable by the formula when a is 0.098167, b is 0.008583 and c is 0.005652, and the minimum value of the ratio of the thickness of the semiconductor layer to the thickness of the buffer layer is obtainable by the formula when a is 0.09546, b is −0.003735 and c is −0.012168, wherein the thickness of the nucleation layer is between 0 nm and 36 nm, the thickness of the buffer layer is between 750 nm and 1755 nm, and the thickness of the semiconductor layer is between 515 nm and 1491 nm.

In one embodiment of the invention, the method of forming semiconductor epitaxial structure further includes: forming a spacer layer on the semiconductor layer, wherein the spacer layer is between the barrier layer and the semiconductor layer.

In one embodiment of the invention, the maximum value of the ratio of the thickness of the semiconductor layer to the thickness of the buffer layer is obtainable by the formula when a is 0.10249, b is 0.006845 and c is 0.00583, and the minimum value of the ratio of the thickness of the semiconductor layer to the thickness of the buffer layer is obtainable by the formula when a is −0.6908, b is 0.030257 and c is 0.08209, wherein the thickness of the nucleation layer is between 0 nm and 21 nm, the thickness of the buffer layer is between 750 nm and 1385 nm, and the thickness of the semiconductor layer is between 515 nm and 1141 nm.

Based on the above, according to the embodiments of the invention, by setting different thicknesses for the nucleation layer and obtaining the maximum value or the minimum value of the ratio of the thickness of the semiconductor layer to the thickness of the buffer layer through the formulae above, the bowing and the curvature of the semiconductor epitaxial structure may be less than or equal to a predetermined value. As a result, defects such as slip lines, bowing, cracks, and even fragmentation may be prevented from happening so that the yield of the semiconductor epitaxial structure may be improved.

To make the aforementioned more comprehensible, several embodiments accompanied with drawings are described in detail as follows.

### BRIEF DESCRIPTION OF THE DRAWINGS

FIG. 1 is a cross-sectional view of a semiconductor epitaxial structure according a first embodiment of the invention.

FIG. 2 is a cross-sectional view of a semiconductor epitaxial structure according a second embodiment of the invention.

### DETAILED DESCRIPTION

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

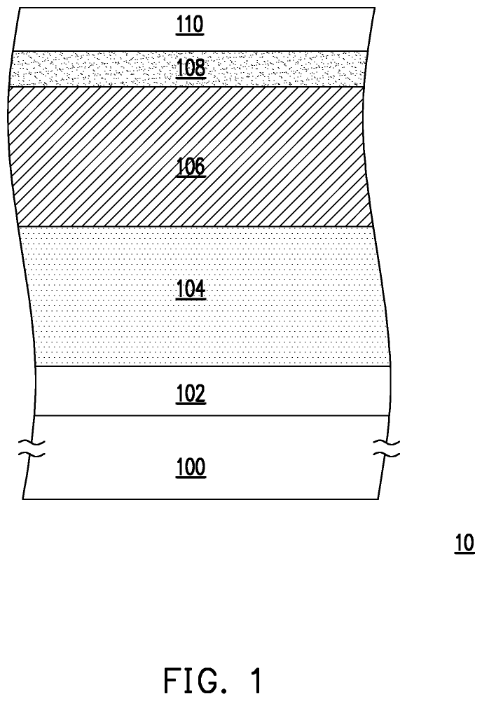

FIG. 1 is a cross-sectional view of a semiconductor epitaxial structure according a first embodiment of the invention. The semiconductor epitaxial structure of the following embodiments can be applied in the field of field effect transistors, such as high power field-effect transistors, high efficiency transistors or high electron mobility transistors (HEMT).

Referring to FIG. 1, a semiconductor epitaxial structure 10 according to the first embodiment of the invention includes a substrate 100, a nucleation layer 102, a buffer layer 104, a semiconductor layer 106, a barrier layer 108 and a cap layer 110 in order from bottom to top. A method of forming the semiconductor epitaxial structure 10 is described as follows.

First, the substrate 100 is provided. In one embodiment, the substrate 100 can be regarded as a growth substrate, and a material thereof may be, for example, sapphire, silicon carbide (SiC), aluminum nitride (AlN), silicon (Si), germanium (Ge), or gallium arsenide (GaAs), indium phosphide (InP), gallium phosphide (GaP), gallium nitride (GaN) or a combination thereof. In this embodiment, the substrate 100 may be a silicon substrate, and its crystal plane may be, for example, but not limited to (111), (110), (100), and the like. In other embodiments, the substrate 100 may also be a silicon-on-insulator (SOI) substrate.

Subsequently, the nucleation layer 102 is selectively formed on the substrate 100. In one embodiment, the nucleation layer 102 may include an AlN layer, an Al layer, or a combination thereof. The nucleation layer 102 may be formed by, for example, a metal organic chemical vapor deposition (MOCVD) or a molecular beam epitaxy (MBE) and has a thickness between 0 nm and 50 nm. In certain embodiments, the nucleation layer 102 may prevent a reflow phenomenon of the eutectic metal caused by Si of the substrate 100 reacting with Ga of the buffer layer 104 or the semiconductor layer 106 formed later. In an alternative embodiment, the nucleation layer 102 may reduce a defect density between the substrate 100 and the buffer layer 104 formed later, so as to reduce the stress.

Then, the buffer layer 104 is formed on the nucleation layer 102 so that the nucleation layer 102 is located between the substrate 100 and the buffer layer 104. In one embodiment, the buffer layer 104 may be a superlattice structure and/or a graded structure. The superlattice structure may include at least two different laminated structures. For instance, the buffer layer 104 includes a first laminated layer, a second laminated layer and a third laminated layer in order from bottom to top. The first laminated layer includes a plurality of AlN layers and a plurality of AlₓGa₁₋ₓN layers that are alternately stacked; the second laminated layer includes a plurality of AlN layers and a plurality of AlₓGa_{1-y}N layers that are alternately stacked; and the third laminated layer includes a plurality of AlN layers and a plurality of AlₓGa_{1-z}N layers that are alternately stacked, wherein x>y>z. That is, the Al content in the buffer layer 104 decreases in a direction from the nucleation layer 102 toward the semiconductor layer 106 formed later. On the other hand, the graded structure refers to a layer having a concentration change in the entire buffer layer 104. For instance, the buffer layer 104 includes a plurality of AlN layers and a plurality of AlₓGa₁₋ₓN layers. The X value may gradually change in the direction from the nucleation layer 102 toward the semiconductor layer 106 formed later. Here, the so-called “graded” may be step grading, continuous grading, discontinuous grading or a combination thereof.

It is worth noting that the buffer layer 104 can ease the stress accumulation caused by the lattice constant between the substrate 100 (or the nucleation layer 102) and the semiconductor layer 106. Therefore, the buffer layer 104 in this embodiment can reduce the stress caused by the difference in thermal expansion coefficient between the semiconductor layer 106 and the substrate 100 to avoid cracks or fragmentation. In addition, the Al content of the buffer layer 104 closest to the nucleation layer 102 is higher than the Al content of the buffer layer 104 closest to the semiconductor layer 106, which can improve the epitaxial quality and facilitate the subsequent device development.

In certain embodiments, the buffer layer 104 may be formed by, for example, a metal organic chemical vapor deposition (MOCVD) or a molecular beam epitaxy (MBE) and has a thickness between 750 nm and 1800 nm. In other embodiments, a material of the buffer layer 104 includes a laminated structure composed of a plurality of AlN layers and a plurality of AlGaN layers, a laminated structure composed of a plurality of AlN layers and a plurality of GaN layers, a laminated structure composed of a plurality of GaN layers and a plurality of AlGaN layers, etc.

Next, the semiconductor layer 106 is formed on the buffer layer 104 so that the buffer layer 104 is located between the nucleation layer 102 and the semiconductor layer 106. In an embodiment, the semiconductor layer 106 may be a nitride semiconductor layer, such as an undoped or unintentionally doped gallium nitride (GaN) layer, a carbon-doped GaN layer, an iron-doped GaN layer or a combination thereof. In an alternative embodiment, the semiconductor layer 106 may be formed by, for example, a metal organic chemical vapor deposition (MOCVD) or a molecular beam epitaxy (MBE) and has a thickness between 515 nm and 1500 nm.

In other embodiments, the semiconductor layer 106 may include a bottom layer and a channel layer disposed on the bottom layer. 2-dimensional electron gas (2DEG) having a high electron mobility may be formed in the channel layer to form the high electron mobility transistor (HEMT).

Then, the barrier layer 108 is formed on the semiconductor layer 106 so that the semiconductor layer 106 is located between the buffer layer 104 and the barrier layer 108. In one embodiment, a material of the barrier layer 108 includes AlGaN, AlN, AlInN, InN, AlGnInN or a combination thereof. In certain embodiments, the barrier layer 108 may be formed by, for example, a metal organic chemical vapor deposition (MOCVD) or a molecular beam epitaxy (MBE) and has a thickness between 4 nm and 30 nm.

Next, the cap layer 110 is formed on the barrier layer 108 so that the barrier layer 108 is located between the semiconductor layer 106 and the cap layer 110. In one embodiment, a material of the cap layer 110 includes GaN, Si₃N₄ or a combination thereof. In certain embodiments, the barrier layer 108 may be formed by, for example, a metal organic chemical vapor deposition (MOCVD), a molecular beam epitaxy (MBE) or a plasma enhanced chemical vapor deposition (PECVD) and has a thickness between 2 nm and 4 nm.

It should be noted that, in this embodiment, in a case where a curvature of the semiconductor epitaxial structure 10 is less than or equal +/−100 km⁻¹ and/or in a case where a bowing is less than or equal to +/−30 μm, a maximum value or a minimum value of a ratio of the thickness of the semiconductor layer 106 to the thickness of the buffer layer 104 is represented as a formula of: Y=aX1−bX2+cX3, X1≥0 nm, X2≥750 nm, X3≥515 nm, wherein X1 is the thickness of the nucleation layer 102, X2 is the thickness of the buffer layer 104, X3 is the thickness of the semiconductor layer 106, a, b and c are constants respectively, and Y is the ratio of the thickness of the semiconductor layer 106 to the thickness of the buffer layer 104 (X3/X2) and falls between the maximum value or the minimum value. Here, the so-called “curvature” refers to a bending degree of the semiconductor epitaxial structure during the epitaxial process. The temperature of the semiconductor epitaxial structure at the time may be between 700° C. and 1200° C. In addition, the so-called “bowing” refers to a bending degree of the semiconductor epitaxial structure at room temperature, where the room temperature may be between 20° C. and 30° C.

In general, when the curvature of the semiconductor epitaxial structure is greater than +/−100 km⁻¹, the bowing of the semiconductor epitaxial structure cooled down to room temperature will be greater than +/−30 μm. This result is called plastic deformation. The so-called “plastic deformation” means that when a material is deformed by an external force, it cannot return to its original state if it passes a certain limit. Such deformation is called plastic deformation. That is, when the curvature of the semiconductor epitaxial structure is greater than +/−100 km⁻¹, the bowing of the semiconductor epitaxial structure cannot be restored to the original state even when it is cooled down to room temperature. Therefore, in the embodiment of the invention, the curvature of the semiconductor epitaxial structure may be made to be less than or equal to +/−100 km⁻¹ so that the bowing of the semiconductor epitaxial structure can be less than or equal to +/−30 μm after being cooled down to room temperature. Accordingly, plastic deformation may be prevented from happening so that the yield of the semiconductor epitaxial structure may be improved.

In certain embodiments, the maximum value of the ratio of the thickness of the semiconductor layer 106 to the thickness of the buffer layer 104 may be obtained by the formula when a is 0.098167, b is 0.008583 and c is 0.005652. That is, the thickness of the nucleation layer 102 is set first, and a preset thickness of the nucleation layer 102 (e.g., X1=0 nm, 10 nm, 20 nm or 36 nm) and a minimum thickness of the buffer layer 104 (e.g., X2=750 nm) are then substituted into a formula (1) of:

Y=0.098167×X1−0.008583×X2+0.005652×X3 (1)

Accordingly, in the case where the curvature of the semiconductor epitaxial structure 10 is less than or equal +/−100 km⁻¹ and/or in the case where the bowing is less than or equal to +/−30 μm, when the nucleation layer 102 is the preset thickness, the maximum value of the ratio of the thickness of the semiconductor layer 106 to the thickness of the buffer layer 104 (i.e., the maximum value of the ratio of the thickness of the semiconductor layer 106 divided by the thickness of the buffer layer 104) may then be obtained.

In order to prove the feasibility of the invention, multiple examples are given below to further explain the semiconductor epitaxial structure 10 of the invention. Although the following experiments are described, the materials used, their amounts and ratios, processing details, processing flow and the like can be appropriately changed without going beyond the scope of the invention. Therefore, the invention should not be interpreted restrictively based on the experiments described below.

TABLE 1

| | | | | The ratio Y of | | |
|---|---|---|---|---|---|---|
| | | | | the thickness | | |
| | | | | of the | Value | |
| | The | The | | semiconductor | obtained by | |
| | thickness | thickness | The thickness | layer to the | substituting | |
| | X1 of the | X2 of the | X3 of the | thickness of | X1, X2 and | |
| | nucleation | buffer | semiconductor | the buffer | X3 into the | |
| Sample | layer (nm) | layer (nm) | layer (nm) | layer | formula (1) | Comparison |
| Example | 0 | 750 | 1491 | 1.99 | 1.99 | Equal |
| 1 | | | | | | |
| Example | 10 | 750 | 1264 | 1.69 | 1.69 | Equal |
| 2 | | | | | | |
| Example | 20 | 750 | 1036 | 1.38 | 1.38 | Equal |
| 3 | | | | | | |
| Example | 36 | 750 | 671 | 0.89 | 0.89 | Equal |
| 4 | | | | | | |

### Example 1 to Example 4

A silicon substrate is provided. Next, a nucleation layer (AlN layer), a buffer layer (a superlattice structure formed by alternately stacking multiple AlN layers and AlGaN layers), and a semiconductor layer (undoped and doped GaN layers) are sequentially formed on the silicon substrate by the MOCVD. The thickness of the nucleation layer, the thickness of the buffer layer and the thickness of the semiconductor layer are shown in Table 1. Then, the bending degrees of the semiconductor epitaxial structures in Example 1 to Example 4 are measured. In Example 1 to Example 4, the semiconductor epitaxial structures all have the curvature less than or equal to +/−100 km⁻¹ and/or the bowing less than or equal to +/−30 μm.

As can be seen from Table 1, the thicknesses X1 of the nucleation layer, the thicknesses X2 of the buffer layer, and the thicknesses X3 of the semiconductor layer measured in Example 1 to Example 4 all satisfy the formula (1) above. That is, the left and right sides of the equal sign in the formula (1) are equal. Therefore, in the embodiment of the invention, different thicknesses may be set for the nucleation layer, and the maximum value of the ratio Y of the thickness of the semiconductor layer to the thickness of the buffer layer may be obtained by using the formula (1) above.

In another embodiment, the maximum value of the ratio of the thickness of the semiconductor layer 106 to the thickness of the buffer layer 104 may be obtained by the formula when a is 0.09546, b is −0.003735 and c is −0.012168. That is, the thickness of the nucleation layer 102 is set first, and a preset thickness of the nucleation layer 102 (e.g., X1=0 nm, 10 nm, 20 nm or 36 nm) and a minimum thickness of the semiconductor layer 106 (e.g., X3=515 nm) are then substituted into a formula (2) of:

Y=0.09546×X1+0.003735×X2−0.012168×X3 (2)

Accordingly, in the case where the curvature of the semiconductor epitaxial structure 10 is less than or equal +/−100 km⁻¹ and/or in the case where the bowing is less than or equal to +/−30 μm, when the nucleation layer 102 is the preset thickness, the minimum value of the ratio of the thickness of the semiconductor layer 106 to the thickness of the buffer layer 104 (i.e., the minimum value of the ratio of the thickness of the semiconductor layer 106 divided by the thickness of the buffer layer 104) may then be obtained.

TABLE 2

| | | | | The ratio Y of | | |
|---|---|---|---|---|---|---|
| | | | | the thickness | | |
| | | | | of the | Value | |
| | The | The | | semiconductor | obtained by | |
| | thickness | thickness | The thickness | layer to the | substituting | |
| | X1 of the | X2 of the | X3 of the | thickness of | X1, X2 and | |
| | nucleation | buffer | semiconductor | the buffer | X3 into the | |
| Sample | layer (nm) | layer (nm) | layer (nm) | layer | formula (2) | Comparison |
| Example | 0 | 1755 | 515 | 0.29 | 0.29 | Equal |
| 5 | | | | | | |
| Example | 10 | 1510 | 515 | 0.34 | 0.33 | Similar |
| 6 | | | | | | |
| Example | 20 | 1279 | 515 | 0.40 | 0.42 | Similar |
| 7 | | | | | | |
| Example | 36 | 908 | 515 | 0.57 | 0.56 | Similar |
| 8 | | | | | | |

### Example 5 to Example 8

The forming steps in Example 5 to Example 8 are similar to the forming steps in Example 1 to Example 4, wherein the thickness of the nucleation layer, the thickness of the buffer layer and the thickness of the semiconductor layer are shown in Table 2. Then, the bending degrees of the semiconductor epitaxial structures in Example 5 to Example 8 are measured. In Example 5 to Example 8, the semiconductor epitaxial structures all have the curvature less than or equal to +/−100 km⁻¹ and/or the bowing less than or equal to +/−30 μm.

As can be seen from Table 2, the thicknesses X1 of the nucleation layer, the thicknesses X2 of the buffer layer, and the thicknesses X3 of the semiconductor layer measured in Example 5 to Example 8 all satisfy the formula (2) above. That is, the left and right sides of the equal sign in the formula (2) are equal or similar. Therefore, in the embodiment of the invention, different thicknesses may be set for the nucleation layer, and the minimum value of the ratio Y of the thickness of the semiconductor layer to the thickness of the buffer layer may be obtained by using the formula (2) above.

In addition, as can be known from Table 1 and Table 2, when the thickness of the nucleation layer is 0 nm to 36 nm, the thickness of the buffer layer may be between 750 nm and 1755 nm, and the thickness of the semiconductor layer may be between 515 nm and 1491 nm. In addition, the maximum value of the ratio Y of the thickness of the semiconductor layer to the thickness of the buffer layer may be between 0.89 and 1.99, and the minimum value may be between 0.29 and 0.56. In other words, within an interval of the thickness range or an interval of the ratio Y described above, the curvature of the semiconductor epitaxial structure may be less than or equal to +/−100 km⁻¹ and/or the curvature may be less than or equal to +/−30 μm. Accordingly, defects such as slip lines, bowing, cracks, and even fragmentation may be prevented from happening so that the yield of the semiconductor epitaxial structure may be improved.

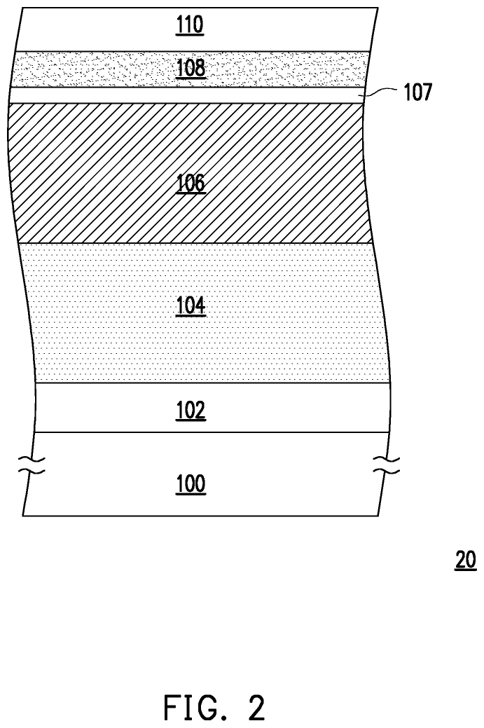

FIG. 2 is a cross-sectional view of a semiconductor epitaxial structure according a second embodiment of the invention.

Referring to FIG. 2, basically, a semiconductor epitaxial structure 20 of the second embodiment is similar to the semiconductor epitaxial structure 10 of the first embodiment. The difference between the two is that the semiconductor epitaxial structure 20 of the second embodiment further includes a spacer layer 107 disposed between the semiconductor layer 106 and the barrier layer 108. In one embodiment, the spacer layer 107 may include an AlN layer. In certain embodiments, the spacer layer 107 may be formed by, for example, a metal organic chemical vapor deposition (MOCVD) or a molecular beam epitaxy (MBE) and has a thickness between 1 nm and 2 nm. In another embodiment, a material of the spacer layer 107 is different from a material of the barrier layer 108, and a lattice constant of the spacer layer 107 may be smaller than a lattice constant of the barrier layer 108. In an alternative embodiment, the spacer layer 107 may increase the electron mobility and increase a carrier confinement capability, thereby improving the 2DEG characteristics.

It should be noted that, in this embodiment, in a case where a curvature of the semiconductor epitaxial structure 20 is less than or equal +/−100 km⁻¹ and/or in a case where a bowing is less than or equal to +/−30 μm, a maximum value or a minimum value of a ratio of the thickness of the semiconductor layer 106 to the thickness of the buffer layer 104 is represented as a formula of: Y=aX1−bX2+cX3, X1≥0 nm, X2≥750 nm, X3≥515 nm, wherein X1 is the thickness of the nucleation layer 102, X2 is the thickness of the buffer layer 104, X3 is the thickness of the semiconductor layer 106, a, b and c are constants respectively, and Y is the ratio of the thickness of the semiconductor layer 106 to the thickness of the buffer layer 104 (X3/X2) and falls between the maximum value or the minimum value.

For instance, in certain embodiments, the maximum value of the ratio of the thickness of the semiconductor layer 106 to the thickness of the buffer layer 104 may be obtained by the formula when a is 0.10249, b is 0.006845 and c is 0.00583. That is, the thickness of the nucleation layer 102 is set first, and a preset thickness of the nucleation layer 102 (e.g., X1=0 nm, 10 nm, 20 nm or 21 nm) and a minimum thickness of the buffer layer 104 (e.g., X2=750 nm) are then substituted into a formula (3) of:

Y=0.10249×X1−0.006845×X2+0.00583×X3 (3)

Accordingly, in the case where the curvature of the semiconductor epitaxial structure 20 is less than or equal +/−100 km⁻¹ and/or in the case where the bowing is less than or equal to +/−30 μm, when the nucleation layer 102 is the preset thickness, the maximum value of the ratio of the thickness of the semiconductor layer 106 to the thickness of the buffer layer 104 may then be obtained.

In order to prove the feasibility of the invention, multiple examples are given below to further explain the semiconductor epitaxial structure 20 of the invention.

TABLE 3

| | | | | The ratio Y of | | |
|---|---|---|---|---|---|---|
| | | | | the thickness | | |
| | | | | of the | Value | |
| | The | The | | semiconductor | obtained by | |
| | thickness | thickness | The thickness | layer to the | substituting | |
| | X1 of the | X2 of the | X3 of the | thickness of | X1, X2 and | |
| | nucleation | buffer | semiconductor | the buffer | X3 into the | |
| Sample | layer (nm) | layer (nm) | layer (nm) | layer | formula (3) | Comparison |
| Example | 0 | 750 | 1141 | 1.52 | 1.52 | Equal |
| 9 | | | | | | |
| Example | 10 | 750 | 913 | 1.22 | 1.21 | Similar |
| 10 | | | | | | |
| Example | 20 | 750 | 685 | 0.91 | 0.91 | Equal |
| 11 | | | | | | |
| Example | 21 | 750 | 662 | 0.88 | 0.88 | Equal |
| 12 | | | | | | |

### Example 9 to Example 12

A silicon substrate is provided. Next, a nucleation layer (AlN layer), a buffer layer (a superlattice structure formed by alternately stacking multiple AlN layers and AlGaN layers), a semiconductor layer (undoped and doped GaN layers) and a spacer layer (AlN layer) are sequentially formed on the silicon substrate by the MOCVD. The thickness of the nucleation layer, the thickness of the buffer layer and the thickness of the semiconductor layer are shown in Table 3, and the thickness of the spacer layer is approximately 1 nm. Then, the bending degrees of the semiconductor epitaxial structures in Example 9 to Example 12 are measured. In Example 9 to Example 12, the semiconductor epitaxial structures all have the curvature less than or equal to +/−100 km⁻¹ and/or the bowing less than or equal to +/−30 μm.

As can be seen from Table 3, the thicknesses X1 of the nucleation layer, the thicknesses X2 of the buffer layer, and the thicknesses X3 of the semiconductor layer measured in Example 9 to Example 12 all satisfy the formula (3) above. That is, the left and right sides of the equal sign in the formula (3) are equal or similar. Therefore, in the embodiment of the invention, different thicknesses may be set for the nucleation layer, and the maximum value of the ratio Y of the thickness of the semiconductor layer to the thickness of the buffer layer may be obtained by using the formula (3) above.

In another embodiment, the maximum value of the ratio of the thickness of the semiconductor layer 106 to the thickness of the buffer layer 104 may be obtained by the formula when a is −0.6908, b is 0.030257 and c is 0.08209. That is, the thickness of the nucleation layer 102 is set first, and a preset thickness of the nucleation layer 102 (e.g., X1=0 nm, 10 nm, 20 nm or 21 nm) and a minimum thickness of the semiconductor layer 106 (e.g., X3=515 nm) are then substituted into a formula (4) of:

Y=−0.6908×X1−0.030257×X2+0.08209×X3 (4)

Accordingly, in the case where the curvature of the semiconductor epitaxial structure 20 is less than or equal +/−100 km⁻¹ and/or in the case where the bowing is less than or equal to +/−30 μm, when the nucleation layer 102 is the preset thickness, the minimum value of the ratio of the thickness of the semiconductor layer 106 to the thickness of the buffer layer 104 may then be obtained.

TABLE 4

| | | | | The ratio Y of | | |
|---|---|---|---|---|---|---|
| | | | | the thickness | | |
| | | | | of the | Value | |
| | The | The | | semiconductor | obtained by | |
| | thickness | thickness | The thickness | layer to the | substituting | |
| | X1 of the | X2 of the | X3 of the | thickness of | X1, X2 and | |
| | nucleation | buffer | semiconductor | the buffer | X3 into the | |
| Sample | layer (nm) | layer (nm) | layer (nm) | layer | formula (4) | Comparison |
| Example | 0 | 1385 | 515 | 0.37 | 0.37 | Equal |
| 13 | | | | | | |
| Example | 10 | 1154 | 515 | 0.45 | 0.45 | Equal |
| 14 | | | | | | |
| Example | 20 | 922 | 515 | 0.56 | 0.56 | Equal |
| 15 | | | | | | |
| Example | 21 | 899 | 515 | 0.57 | 0.57 | Equal |
| 16 | | | | | | |

### Example 13 to Example 16

The forming steps in Example 13 to Example 16 are similar to the forming steps in Example 9 to Example 12, wherein the thickness of the nucleation layer, the thickness of the buffer layer and the thickness of the semiconductor layer are shown in Table 4, and the thickness of the spacer layer is approximately 1 nm. Then, the bending degrees of the semiconductor epitaxial structures in Example 13 to Example 16 are measured. In Example 13 to Example 16, the semiconductor epitaxial structures all have the curvature less than or equal to +/−100 km⁻¹ and/or the bowing less than or equal to +/−30 μm.

As can be seen from Table 4, the thicknesses X1 of the nucleation layer, the thicknesses X2 of the buffer layer, and the thicknesses X3 of the semiconductor layer measured in Example 13 to Example 16 all satisfy the formula (4) above. That is, the left and right sides of the equal sign in the formula (4) are equal. Therefore, in the embodiment of the invention, different thicknesses may be set for the nucleation layer, and the minimum value of the ratio Y of the thickness of the semiconductor layer to the thickness of the buffer layer may be obtained by using the formula (4) above.

As can be known from Table 3 and Table 4, when the thickness of the nucleation layer is 0 nm to 21 nm, the thickness of the buffer layer may be between 750 nm and 1385 nm, and the thickness of the semiconductor layer may be between 515 nm and 1141 nm. In addition, the maximum value of the ratio Y of the thickness of the semiconductor layer to the thickness of the buffer layer may be between 0.88 and 1.52, and the minimum value may be between 0.37 and 0.57. In other words, within an interval of the thickness range or an interval of the ratio Y described above, the curvature of the semiconductor epitaxial structure may be less than or equal to +/−100 km⁻¹ and/or the curvature may be less than or equal to +/−30 μm. Accordingly, defects such as slip lines, bowing, cracks, and even fragmentation may be prevented from happening so that the yield of the semiconductor epitaxial structure may be improved.

In summary, according to the embodiments of the invention, by setting different thicknesses for the nucleation layer and obtaining the maximum value or the minimum value of the ratio of the thickness of the semiconductor layer to the thickness of the buffer layer through the formulae above, the bowing and the curvature of the semiconductor epitaxial structure may be less than or equal to a predetermined value. As a result, defects such as slip lines, bowing, cracks, and even fragmentation may be prevented from happening so that the yield of the semiconductor epitaxial structure may be improved.

Although the present disclosure has been described with reference to the above embodiments, it will be apparent to one of ordinary skill in the art that modifications to the described embodiments may be made without departing from the spirit of the disclosure. Accordingly, the scope of the disclosure will be defined by the attached claims and not by the above detailed descriptions.

1. A semiconductor epitaxial structure, comprising:
a substrate;
a nucleation layer disposed on a substrate;
a buffer layer disposed on the nucleation layer;
a semiconductor layer disposed on the buffer layer;
a barrier layer disposed on the semiconductor layer; and
a cap layer disposed on the barrier layer, wherein in a case where a bowing of the semiconductor epitaxial structure is less than or equal to +/−30 μm, a maximum value or a minimum value of a ratio of a thickness of the semiconductor layer to a thickness of the buffer layer is represented as a formula of:
Y=aX1−bX2+cX3, X1≥0 nm, X2≥750 nm, X3≥515 nm,
wherein X1 is a thickness of the nucleation layer, X2 is the thickness of the buffer layer, X3 is the thickness of the semiconductor layer, a, b and c are constants respectively, and Y is the ratio of the thickness of the semiconductor layer to the thickness of the buffer layer (X3/X2) and falls between the maximum value or the minimum value.

2. The semiconductor epitaxial structure according to claim 1, wherein the maximum value of the ratio of the thickness of the semiconductor layer to the thickness of the buffer layer is obtainable by the formula when a is 0.098167, b is 0.008583 and c is 0.005652, and
the minimum value of the ratio of the thickness of the semiconductor layer to the thickness of the buffer layer is obtainable by the formula when a is 0.09546, b is −0.003735 and c is −0.012168,
wherein the thickness of the nucleation layer is between 0 nm and 36 nm, the thickness of the buffer layer is between 750 nm and 1755 nm, and the thickness of the semiconductor layer is between 515 nm and 1491 nm.

3. The semiconductor epitaxial structure according to claim 1, wherein the maximum value is between 0.89 and 1.99, and the minimum value is between 0.29 and 0.56.

4. The semiconductor epitaxial structure according to claim 1, further comprising: a spacer layer disposed between the barrier layer and the semiconductor layer.

5. The semiconductor epitaxial structure according to claim 4, wherein the maximum value of the ratio of the thickness of the semiconductor layer to the thickness of the buffer layer is obtainable by the formula when a is 0.10249, b is 0.006845 and c is 0.00583, and
the minimum value of the ratio of the thickness of the semiconductor layer to the thickness of the buffer layer is obtainable by the formula when a is −0.6908, b is 0.030257 and c is 0.08209,
wherein the thickness of the nucleation layer is between 0 nm and 21 nm, the thickness of the buffer layer is between 750 nm and 1385 nm, and the thickness of the semiconductor layer is between 515 nm and 1141 nm.

6. The semiconductor epitaxial structure according to claim 4, wherein the maximum value is between 0.88 and 1.52, and the minimum value is between 0.37 and 0.57.

7. A forming method of semiconductor epitaxial structure, comprising:
forming a nucleation layer on a substrate;
forming a buffer layer on the nucleation layer;
forming a semiconductor layer on the buffer layer;
forming a barrier layer on the semiconductor layer; and
forming a cap layer on the barrier layer, wherein in a case where a curvature of the semiconductor epitaxial structure is less than or equal to +/−100 km⁻¹, a maximum value or a minimum value of a ratio of a thickness of the semiconductor layer to a thickness of the buffer layer is represented as a formula of:
Y=aX1−bX2+cX3, X≥10 nm, X2≥750 nm, X3≥515 nm,
wherein X1 is a thickness of the nucleation layer, X2 is the thickness of the buffer layer, X3 is the thickness of the semiconductor layer, a, b and c are constants respectively, and Y is the ratio of the thickness of the semiconductor layer to the thickness of the buffer layer (X3/X2) and falls between the maximum value or the minimum value.

8. The forming method of semiconductor epitaxial structure according to claim 7, wherein the maximum value of the ratio of the thickness of the semiconductor layer to the thickness of the buffer layer is obtainable by the formula when a is 0.098167, b is 0.008583 and c is 0.005652, and
the minimum value of the ratio of the thickness of the semiconductor layer to the thickness of the buffer layer is obtainable by the formula when a is 0.09546, b is −0.003735 and c is −0.012168,
wherein the thickness of the nucleation layer is between 0 nm and 36 nm, the thickness of the buffer layer is between 750 nm and 1755 nm, and the thickness of the semiconductor layer is between 515 nm and 1491 nm.

9. The forming method of semiconductor epitaxial structure according to claim 7, further comprising forming a spacer layer on the semiconductor layer, wherein the spacer layer is between the barrier layer and the semiconductor layer.

10. The forming method of semiconductor epitaxial structure according to claim 9, wherein the maximum value of the ratio of the thickness of the semiconductor layer to the thickness of the buffer layer is obtainable by the formula when a is 0.10249, b is 0.006845 and c is 0.00583, and
the minimum value of the ratio of the thickness of the semiconductor layer to the thickness of the buffer layer is obtainable by the formula when a is −0.6908, b is 0.030257 and c is 0.08209,
wherein the thickness of the nucleation layer is between 0 nm and 21 nm, the thickness of the buffer layer is between 750 nm and 1385 nm, and the thickness of the semiconductor layer is between 515 nm and 1141 nm.
